(19) United States
(12) Patent Application Publication
(10) Pub. No.: US 2024/0150647 A1
(43) Pub. Date: May 9, 2024

(54) PHOSPHOR POWDER, COMPOSITE, AND LIGHT-EMITTING DEVICE

(71) Applicant: DENKA COMPANY LIMITED, Tokyo (JP)

(72) Inventors: Moeko TANAKA, Tokyo (JP); Tomohiro NOMIYAMA, Tokyo (JP)

(73) Assignee: DENKA COMPANY LIMITED, Tokyo (JP)

(21) Appl. No.: 18/282,590

(22) PCT Filed: Mar. 11, 2022
(86) PCT No.: PCT/JP2022/010949

§ 371 Date: Sep. 18, 2023

(30) Foreign Application Priority Data
Mar. 22, 2021 (JP) 2021-047031

(51) Int. Cl. C09K 11/77; C01B 21/082; C09K 11/02; H01L 33/50

(52) U.S. Cl. CPC C09K 11/77348; C01B 21/0826; C09K 11/02; H01L 33/502; C01P 2002/54; C01P 2004/52; C01P 2004/62; C01P 2006/60

(57) ABSTRACT

A phosphor powder consisting of a red phosphor represented by a general formula (Srₓ, Ca_{1-x-y}, Eu_{y})AlSi(N,O)₃ having the same crystal phase as that of CaAlSiN₃. In the general formula, relationships of x<1 and 1−x−y>0 are satisfied. In a case where a cumulative 10% value of the phosphor powder in a volume-based particle size distribution curve is defined as D₁₀, a cumulative 50% value is defined as D₅₀, and a cumulative 90% value is defined as D₉₀, a value of D₅₀ is more than 20 μm and 40 μm or less, and a value of (D₉₀−D₁₀)/D₅₀ is 1.12 or less.

### TECHNICAL FIELD

The present invention relates to a phosphor powder, a composite, and a light-emitting device.

### BACKGROUND ART

In order to manufacture a white LED, a red phosphor that converts blue light from a blue LED chip into red light is being studied. As a red phosphor, a phosphor represented by a general formula MAlSiN₃ (M is one or two or more elements selected from the group consisting of Mg, Ca, Sr, Ba, and Eu) is known. For reference, a phosphor in which M is Ca is often written as “CASN”, and a phosphor in which M contains two elements, Sr and Ca, is often written as “SCASN”.

As a specific example, Patent Document 1 discloses a phosphor containing a crystal phase represented by a general formula, MₐSr_{b}Ca_{c}Al_{d}SiₑN_{f} and having a quantum efficiency maintenance rate of equal to or more than 85% at photoexcitation of 4000 mW/mm². In this general formula, M represents an active element, 0<a<0.05, 0.95≤b≤1, 0≤c≤0.1, a+b+c=1, 0.7≤d≤1.3, 0.7≤e≤1.3, and 2.5≤f≤3.5.

### RELATED DOCUMENT

### Patent Document

[Patent Document 1] Japanese Unexamined Patent Publication No. 2019-077800

### SUMMARY OF THE INVENTION

### Technical Problem

So far, various improvements have been made to a red phosphor that converts blue light from a blue LED chip into red light. However, there is still room for improvement in terms of brightness of a white LED to which a red phosphor is used.

For example, a red phosphor is often used in combination with another phosphor (usually a yellow or green phosphor) to configure a white LED package. Therefore, in addition to performance of the red phosphor itself, it is preferable that excellent brightness is obtained in the “combination” of the red phosphor and other phosphors.

The present invention has been made in view of such circumstances. One of objects of the present invention is to improve the brightness of the white LED by improving the red phosphor.

### Solution to Problem

The inventors of the present invention completed the invention provided below.

According to the present invention, there is provided
a phosphor powder consisting of a red phosphor represented by a general formula (Srₓ, Ca_{1-x-y}, Eu_{y})AlSi(N,O)₃ having the same crystal phase as that of CaAlSiN₃,
in which relationships of x<1 and 1−x−y>0 are satisfied, and
in a case where a cumulative 10% value of the phosphor powder in a volume-based particle size distribution curve is defined as D₁₀, a cumulative 50% value is defined as D₅₀, and a cumulative 90% value is defined as D₉₀, a value of D₅₀ is more than 20 μm and 40 μm or less, and a value of (D₉₀−D₁₀)/D₅₀ is 1.12 or less.

In addition, according to the present invention, there is provided
a composite including the phosphor powder, and a sealing material that seals the phosphor powder.

In addition, according to the present invention, there is provided
a light-emitting device including a light-emitting element that emits excitation light; and
the composite that converts a wavelength of the excitation light.

### Advantageous Effects of Invention

By using the phosphor powder of the present invention, brightness of a white LED can be improved.

### BRIEF DESCRIPTION OF THE DRAWINGS

FIG. 1 is a diagram for illustrating a presumed mechanism in which brightness of a white LED can be improved by using a phosphor powder of the present embodiment.

FIG. 2 is a diagram for illustrating a white LED package of the related art.

FIG. 3 is a schematic cross-sectional view showing an example of a structure of a light-emitting device.

### DESCRIPTION OF EMBODIMENTS

Hereinafter, an embodiment of the present invention will be described in detail while referring to drawings.

In all the drawings, the same constitutional components are denoted by the same reference signs, and description thereof will not be repeated as appropriate.

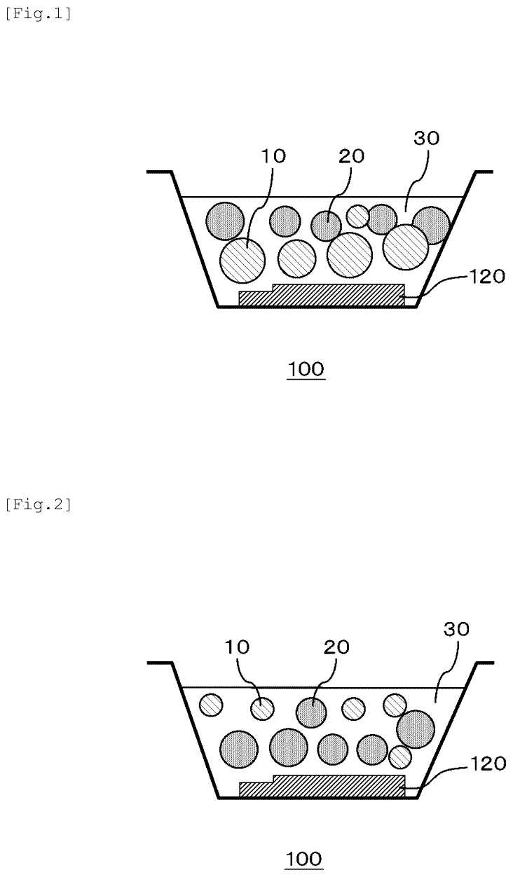

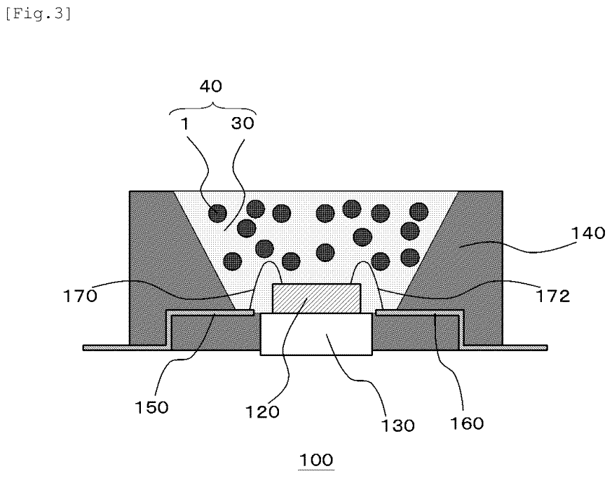

In order to avoid complication, (i) when a plurality of the same constitutional components are present on the same drawing, there may be a case where the reference numeral is given to only one component without giving the reference numeral to all the components; and (ii) in particular, in FIG. 2 and subsequent drawings, there may be a case where the reference numeral is not given again to the same constitutional components as those in FIG. 1.

All the drawings are merely illustrative. A shape or a dimensional ratio of each member in the drawing does not necessarily correspond to an actual article.

In the present specification, the notation “X to Y” in the description of the numerical range indicates X or more and Y or less unless otherwise specified. For example, “1% to 5% by mass” means “equal to or more than 1% by mass and equal to or less than 5% by mass”.

In the present specification, an LED represents an abbreviation for a light emitting diode.

<Phosphor Powder>

The phosphor powder of the present embodiment consists of a red phosphor represented by a general formula (Srₓ, Ca_{1-x-y}, Eu_{y})AlSi(N,O)₃ having the same crystal phase as that of CaAlSiN₃. In the general formula, relationships of x<1 and 1−x−y>0 are satisfied.

In a case where a cumulative 10% value of the phosphor powder of the present embodiment in a volume-based particle size distribution curve is defined as D₁₀, a cumulative 50% value is defined as D₅₀, and a cumulative 90% value is defined as D₉₀, a value of D₅₀ is more than 20 μm and 40 μm or less, and a value of (D₉₀−D₁₀)/D₅₀ is 1.12 or less.

As described above, a red phosphor is often used in combination with another phosphor (usually a yellow or green phosphor) to configure a white LED package. Typically, a white LED package includes a composite in which a mixture of a red phosphor and other phosphors is sealed with a sealing material. The composite is irradiated with blue light from a blue LED chip, thereby obtaining white light.

The present inventors considered that “distribution” or “a way of uneven distribution” of the red phosphor and other phosphors in the composite may be related to the brightness of the white LED.

Specifically, in the design of the typical white LED, an amount of red phosphor used is often smaller than that of other phosphors. Accordingly, the inventors considered that, when the red phosphor is evenly dispersed in the composite, blue light may not be sufficiently converted into red light and this may suppress improvement of the brightness. Based on this idea, in order to improve the brightness, as shown in FIG. 1, it is thought that, in a light-emitting device 100 (the white LED package), it may be preferable that red phosphors 10 are unevenly distributed on a part close to a light-emitting element 120 (which emits blue light) to cause blue light to be preferentially converted into red light.

By proceeding with the above idea, the inventors considered that, as a specific solution, it is preferable to produce the red phosphor 10 having a comparatively great value of D₅₀ and a comparatively sharp particle size distribution and to mix the red phosphor 10, another phosphor 20, and a sealing material 30 to configure a composite. That is, the inventors considered that, by configuring the composite using the red phosphor which is “larger and sinks more easily” than a commonly used yellow or green phosphor (YAG or LuAG), a distribution state of phosphor particles can be realized as shown in FIG. 1 and the brightness of the white LED can be improved.

As the “red phosphor having a comparatively great value of D₅₀ and a comparatively sharp particle size distribution”, the present inventors newly produced a phosphor powder (formed of a red phosphor), specifically, having a value of D₅₀ of more than 20 μm and 40 μm or less and a value of (D₉₀−D₁₀)/D₅₀, which is an index showing sharpness of a particle size distribution, of 1.12 or less.

In addition, by producing the light-emitting device 100 (the white LED package) using this new phosphor powder (the red phosphor) in combination with other phosphors, the brightness could be improved.

For reference, it is considered that, in the light-emitting device 100 (the white LED package) of the related art, since a red phosphor having a comparatively a small particle size and/or a comparatively wide particle size distribution is used, the distribution of the red phosphors 10 and the other phosphors 20 is as shown in FIG. 2, for example.

In addition, as an upper limit value of D₅₀ is 40 μm, there is an advantage that it is possible to suppress occurrence of clogging of a nozzle used in a case of injecting or applying a mixture of a sealing resin and phosphor particles to a package.

The phosphor powder of the present embodiment can be obtained by appropriately selecting raw materials, and selecting a usage ratio of each raw material, a producing procedure, producing conditions, and the like. The selection of raw materials and an amount ratio of raw materials preferably include usage of a large amount of a Sr-containing raw material, addition of “nucleus” which will be described later, and the like. The producing procedure and producing conditions preferably include performing of firing using a container made of a high melting point metal (for example, a container made of tungsten, molybdenum, or tantalum, and the like), making a time of firing comparatively long, and the like. These details will be described later.

The description of the phosphor powder of the present embodiment will be continued.

(Crystal Structure, Elemental Composition, and the Like)

The phosphor powder of the present embodiment consists of a red phosphor represented by a general formula (Srₓ, Ca_{1-x-y}, Eu_{y})AlSi(N,O)₃ having the same crystal phase as that of CaAlSiN₃. In this general formula, relationships of x<1 and 1−x−y>0 are satisfied. Here, (N,O) means that a part of N is unavoidably replaced with O.

The crystal phase can be confirmed by powder X-ray diffraction. The crystal phase is preferably a single phase of a crystal, but may contain a heterogeneous phase as long as it does not significantly affect the properties of the phosphor. The presence or absence of the heterogeneous phase can be determined, for example, by powder X-ray diffraction based on the presence or absence of a peak other than that due to the target crystal phase.

A skeleton structure of CaAlSiN₃ is configured with (Si,Al)—N₄ regular tetrahedrons bonded to each other, and Ca atoms are located in a gap of the skeleton. A part of Ca²⁺ is replaced with Eu²⁺, which acts as a light emission center, to form a red phosphor.

With respect to x, it is preferably 0.9<x<1, more preferably 0.92<x<1, and even more preferably 0.95<x<1. As the findings of the inventors of the present invention, it is preferable that an Sr amount in the phosphor particles of the present embodiment is large, from a viewpoint of improvement of the brightness or improvement of other performance.

With respect to y, it is preferably y<0.1, more preferably 0.0005<y<0.1, and even more preferably 0.001<y<0.05. From a viewpoint of excellent internal quantum efficiency or light emitting intensity, a value of y is preferably appropriately adjusted.

(Particle Size Distribution)

As described above, a value of D₅₀ of the phosphor powder of the present embodiment may be more than 20 μm and equal to or less than 40 μm. The value of D₅₀ is preferably 25 μm or more and 40 μm or less, more preferably 25 μm or more and 35 μm or less, and particularly preferably 30 μm or more and 35 μm or less.

In addition, as described above, a value of (D₉₀−D₁₀)/D₅₀ may be 1.12 or less. This value is preferably 1.11 or less and more preferably 1.10 or less. Although there is no particular lower limit value for the value of (D₉₀−D₁₀)/D₅₀, the lower limit is, for example, 1.05 from a practical aspect such as production cost.

A value of D₁₀ itself is preferably 10 μm or more and 20 μm or less and more preferably 15 μm or more and 19 μm or less.

A value of D₉₀ itself is preferably 30 μm or more and 60 μn or less, more preferably 40 μm or more and 60 μm or less, and even more preferably 45 μm or more and 60 μm or less.

In addition, in the present embodiment, a cumulative 97% value D₉₇ in the volume-based particle size distribution curve is preferably 50 μm or more and 100 μm or less, and more preferably 60 μm or more and 90 μm or less.

In addition, in the present embodiment, a cumulative 100% value D₁₀₀ in the volume-based particle size distribution curve is preferably 80 μm or more and 200 μm or less, and more preferably 100 μm or more and 180 μm or less.

By setting these values not to be excessively large, for example, it is possible to suppress occurrence of clogging of a nozzle used in a case of injecting or applying a mixture of a sealing resin and phosphor particles to a package.

The particle size distribution can be measured based on a volume by a laser diffraction scattering method. Measurement is usually performed by wet type. The details of a pretreatment method of a sample or measurement conditions can be referred to Examples described later.

<Method for Producing Phosphor Powder>

The phosphor powder of the present embodiment can be obtained by appropriately selecting raw materials, a usage ratio of each raw material, a producing procedure, producing conditions, and the like. The phosphor powder of the present embodiment can be preferably produced through the following steps.
Mixing step of mixing a starting raw material to form a raw material mixed powder
Firing step of firing the raw material mixed powder to obtain a fired product

In addition, in the production of the phosphor powder, there may be additional steps other than these steps.

Hereinafter, the mixing step, the firing step, and additional steps other than these steps will be described.

(Mixing Step)

In the mixing step, the starting raw materials are mixed to form a raw material mixed powder.

Examples of the starting raw material include a europium compound, a strontium compound such as strontium nitride, a calcium compound such as calcium nitride, silicon nitride, and aluminum nitride.

The form of each starting raw material is preferably powder state.

Examples of europium compound include an oxide containing europium, a hydroxide containing europium, a nitride containing europium, an oxynitride containing europium, and a halide containing europium. These can be used alone or in combination of two or more. Among them, europium oxide, europium nitride and europium fluoride are preferably used alone, and europium oxide is more preferably used alone.

In the firing step, europium is divided into those for solid solution, those that volatilize, and those that remain as a heterogeneous phase component. The heterogeneous phase component containing europium can be removed by an acid treatment or the like. However, in a case where a significantly large amount thereof is generated, a component insoluble by the acid treatment is generated and the brightness decreases. In addition, as long as it is a heterogeneous phase that does not absorb excess light, it may be in a residual state, and europium may be contained in this heterogeneous phase.

The amount of the europium compound used is not limited, but the europium compound is preferably used in such an amount that, in the general formula described above, the relationship of y<0.1, more preferably 0.0005<y<0.1, and even more preferably 0.001<y<0.05, is satisfied.

Meanwhile, regarding the amount of the strontium compound, the strontium compound is preferably used in such an amount that, in the general formula described above, the relationship of 0.9≤x<1, more preferably 0.92≤x<1, and more preferably 0.95≤x<1, is satisfied.

From a viewpoint of obtaining a phosphor powder having a desired value of D₅₀ or (D₉₀−D₁₀)/D₅₀, it is preferable that the amount of strontium is relatively large in the present embodiment.

In the present embodiment, it is preferable that the starting raw material (raw material mixed powder) contains SCASN phosphor nuclear particles having a median diameter equal to or more than 5 μm and equal to or less than 30 μm. That is, it is preferable that a part of the starting raw material is SCASN phosphor nuclear particles having a median diameter equal to or more than 5 μm and equal to or less than 30 μm. The median diameter is more preferably equal to or more than 10 μm and equal to or less than 20 μm.

In the present specification, the SCASN phosphor nuclear particles are also simply referred to as “nuclear particles”, “nucleus”, and the like.

Although the details are not clear, it is considered that, since the nuclear particles are used, the crystallization proceeds from the nuclear particles as a starting point in the subsequent firing step. Accordingly, it is considered that a way of crystal growth, and the like are different from a case where the firing step is performed without using the nuclear particles (for example, it is considered that, by using the nuclear, crystal growth is promoted to easily obtain larger particles, or generation of extremely large or small particles can be suppressed). Then, probably as a result, it is considered that it is easy to obtain a phosphor powder in which the value of D₅₀ is more than 20 μm and 40 μm or less and the value of (D₉₀−D₁₀)/D₅₀ is 1.12 or less.

As an example, the nuclear particles can be a red phosphor represented by the same general formula as that of the phosphor powder of the present embodiment described above. That is, as an example, the nuclear particles have the same or similar composition as the phosphor powder of the present embodiment, although the value of D₅₀ is not necessarily more than 20 μm and 40 μm or less and the value of (D₉₀−D₁₀)/D₅₀ is not necessarily 1.12 or less.

In a case where nuclear particles are used, the amount thereof is, for example, equal to or more than 1% by mass and equal to or less than 20% by mass, preferably equal to or more than 2′ by mass and equal to or less than 15% by mass, more preferably equal to or more than 2% by mass and equal to or less than 10% by mass, and even more preferably equal to or more than 2% by mass and equal to or less than 7% by mass, in a total amount of the raw material mixed powder.

The nuclear particles can be obtained, for example, by undergoing steps substantially similar to those of the phosphor powder of the present embodiment. That is, in the steps of producing the phosphor powder of the present embodiment, the nuclear particles can be obtained in substantially the same manner, except that the nuclear particles are not added in the mixing step. The composition of the nuclear particles (general formula) is also preferably the same as that of the phosphor powder of the present embodiment.

In the mixing step, the raw material mixed powder can be obtained by using, for example, a method for dry-mixing the starting raw material, a method for wet-mixing in an inert solvent that does not substantially react with each starting raw material, and then removing the solvent, or the like. As a mixing device, for example, a small-sized mill mixer, a V-type mixer, a rocking mixer, a ball mill, a vibration mill, or the like can be used. After the mixing using the device, the aggregates can be removed by a sieve, as needed, to obtain a raw material mixed powder.

In order to suppress a deterioration of the starting raw material and unintentional mixing of oxygen, it is preferable that the mixing step is performed in a nitrogen atmosphere or in an environment where the water content (humidity) is as low as possible.

(Firing Step)

In the firing step, the raw material mixed powder obtained in the mixing step is fired to obtain a fired product.

A firing temperature in the firing step is preferably equal to or higher than 1800° C. and equal to or lower than 2100° C. and more preferably equal to or higher than 1900° C. and equal to or lower than 2000° C. By setting the firing temperature to the lower limit value or higher, the grain growth of the phosphor particles proceeds more effectively. Accordingly, a light absorption rate, an internal quantum efficiency, and an external quantum efficiency can be further improved. By setting the firing temperature to the upper limit value or lower, the decomposition of the phosphor particles can be further suppressed. Accordingly, the light absorption rate, the internal quantum efficiency, and the external quantum efficiency can be further improved.

Other conditions such as a heating time, a heating rate, a heating holding time, and a pressure in the firing step are not particularly limited, and may be appropriately adjusted according to the raw materials used. However, from a viewpoint of making a value of D₅₀ more than 20 μm, typically, the heating holding time is preferably equal to or longer than 10 hours and equal to or shorter than 30 hours and more preferably equal to or longer than 12 hours and equal to or shorter than 30 hours. In addition, the pressure is preferably equal to or more than 0.6 MPa and equal to or less than 10 MPa (gauge pressure). From a viewpoint of controlling oxygen concentration or the like, it is preferable that the firing step is performed in a nitrogen gas atmosphere. That is, it is preferable that the firing step is performed in a nitrogen gas atmosphere having a pressure equal to or more than 0.6 MPa and equal to or less than 10 MPa (gauge pressure).

At the time of firing, it is preferable to fill a container that does not easily react with the mixture during the firing, for example, a container made of a high melting point metal, specifically a container having an inner wall made of tungsten, molybdenum, or tantalum with the mixture, and heat the mixture. Accordingly, the generation of heterogeneous phase can be suppressed.

(Powdering Step)

As an additional step, a powdering step may be performed. The fired product obtained through the firing step is normally granular or lumpy. In a case where the fired product is lumpy and difficult to handle, the fired product can be powderized by using treatments such as crushing, pulverization, and classification alone or in combination.

Specific examples of the treatment method include a method of crushing the sintered compact to a predetermined particle size using a general pulverizer such as a ball mill, a vibration mill, or a jet mill. However, attention needs to be paid to excessive pulverization, because fine particles that easily scatter light may be generated or crystal defects may be caused on a particle surface, resulting in a decrease in light emitting efficiency.

(Annealing Step)

As an additional step, an annealing step may be performed. Specifically, after the firing step, there may be an annealing step of annealing the fired powder at a temperature lower than the firing temperature in the firing step to obtain an annealed powder.

The annealing step is preferably performed in an inert gas such as a rare gas and a nitrogen gas, a reducing gas such as a hydrogen gas, a carbon monoxide gas, a hydrocarbon gas, and an ammonia gas, or a mixed gas thereof, or in a non-oxidizing atmosphere other than pure nitrogen such as a vacuum. The annealing step is particularly preferably performed in a hydrogen gas atmosphere or an argon atmosphere.

The annealing step may be performed under atmospheric pressure, pressurization, or decompression. A heat treatment temperature in the annealing step is preferably equal to or higher than 1300° C. and equal to or lower than 1400° C. The time of the annealing step is not particularly limited, and is preferably equal to or longer than 3 hours and equal to or shorter than 12 hours and more preferably equal to or longer than 5 hours and equal to or shorter than 10 hours.

By performing the annealing step, the light emitting efficiency of the phosphor particles can be sufficiently improved. In addition, the rearrangement of the elements removes strains and defects, so that transparency can also be improved.

In the annealing step, heterogeneous phases may be generated. However, this can be sufficiently removed by a step which will be described later.

(Acid Treatment Step)

As an additional step, an acid treatment step may be performed. In the acid treatment step, the annealed powder obtained in the annealing step is generally acid-treated. Accordingly, at least a part of impurities that do not contribute to light emission can be removed. In addition, it is assumed that the impurities that do not contribute to light emission are generated during the firing step and the annealing step.

As the acid, an aqueous solution containing one or more acids selected from hydrofluoric acid, sulfuric acid, phosphoric acid, hydrochloric acid, and nitric acid can be used. Particularly, hydrofluoric acid, nitric acid, and a mixed acid of hydrofluoric acid and nitric acid are preferable.

The acid treatment can be performed by dispersing the annealed powder in an aqueous solution containing the acid described above. A stirring time is, for example, equal to or longer than 10 minutes and equal to or shorter than 6 hours and preferably equal to or longer than 30 minutes and equal to or shorter than 3 hours. A temperature at the time of stirring can be, for example, equal to or higher than 40° C. and equal to or lower than 90° C. and preferably equal to or higher than 50° C. and equal to or lower than 70° C.

After the acid treatment step, the liquid in which the annealed powder is dispersed may be boiled.

After the acid treatment step, substances other than the phosphor powder may be separated by filtration, and if necessary, the substance attached to the phosphor particles may be washed with water. After washing with water, generally, the phosphor powder is dried by natural drying or drying in a dryer. The dried phosphor powder may be placed in a crucible and heated to modify the surface.

The phosphor powder of the present embodiment can be obtained by a series of steps described above.

<Composite>

The composite includes, for example, the phosphor powder of the present embodiment and a sealing material that seals the phosphor powder. In the composite, the phosphor powder described above is dispersed in the sealing material. As described above, in applications to the white LED, the composite preferably includes the phosphor powder of the present embodiment (described above) and other phosphor powders different therefrom. “Other phosphor powders” are usually yellow or green phosphors, and their specific examples include YAG phosphors, LuAG phosphors, S—SiAlON phosphors, and the like. A ratio of the phosphor powder of the present embodiment and the other phosphor powders in the composite is, for example, in terms of a mass ratio, the phosphor powder of the present embodiment:other phosphor powder=1:99 to 50:50, specifically 1:99 to 30:70, more specifically 1:99 to 10:90.

As the sealing material, a well-known material such as a resin, a glass, and ceramics can be used. Examples of the resin which can be used for the sealing material include transparent resins such as a silicone resin, an epoxy resin, and a urethane resin.

Examples of a method for producing the composite include a producing method for adding the phosphor powder to a liquid sealing material (a resin, a glass, ceramics, or the like), uniformly mixing the mixture, and then curing or sintering the mixture by a heat treatment. At this time, in a case where the composite is produced by sealing (i) the phosphor powder of the present embodiment and (ii) commonly used YAG phosphor, LuAG phosphor, β-SiAlON phosphor, or the like with a liquid sealing material, the phosphor powder of the present embodiment tends to be unevenly distributed to a lower part of the composite.

<Light-Emitting Device>

FIG. 3 is a schematic cross-sectional view showing an example of a structure of a light-emitting device. As shown in FIG. 3, a light-emitting device 100 includes a light-emitting element 120, a heat sink 130, a case 140, a first lead frame 150, a second lead frame 160, a bonding wire 170, a bonding wire 172, and a composite 40.

The light-emitting element 120 is mounted in a predetermined region on the upper surface of the heat sink 130. By mounting the light-emitting element 120 on the heat sink 130, the heat dissipation of the light-emitting element 120 can be enhanced. Further, a packaging substrate may be used instead of the heat sink 130.

The light-emitting element 120 is a semiconductor element that emits excitation light. As the light-emitting element 120, for example, an LED chip that generates light at a wavelength of equal to or more than 300 nm and equal to or less than 500 nm, corresponding to near-ultraviolet to blue light, can be used. One electrode (not shown in the drawings) arranged on the upper surface side of the light-emitting element 120 is connected to the surface of the first lead frame 150 through the bonding wire 170 such as a gold wire. In addition, the other electrode (not shown in the drawings) formed on the upper surface of the light-emitting element 120 is connected to the surface of the second lead frame 160 through the bonding wire 172 such as a gold wire.

In the case 140, a substantially funnel-shaped recess whose hole diameter gradually increases toward the upside from the bottom surface is formed. The light-emitting element 120 is provided on the bottom surface of the recess. The wall surface of the recess surrounding the light-emitting element 120 serves as a reflective plate.

The recess whose wall surface is formed by the case 140 is filled with the composite 40. The composite 40 is a wavelength conversion member that converts excitation light emitted from the light-emitting element 120 into light at a longer wavelength. The composite of the present embodiment described above is used as the composite 40. In FIG. 3, the composite 40 is configured with phosphor particles 1 and the sealing material 30. The phosphor powder of the present embodiment (the red phosphor) is preferably unevenly distributed in a lower part of the composite 40. In addition, the other phosphors (typically YAG phosphor, LuAG phosphor, β-SiAlON phosphor, or the like) are preferably unevenly distributed to an upper part of the composite 40. That is, preferably, among the plurality of phosphor particles 1 shown in FIG. 3, the phosphor particles on the comparatively lower part are the phosphor powder of the present embodiment (the red phosphor), and the phosphor particles on the comparatively upper part are the other phosphor particles.

In addition, in FIG. 1, a surface mounting type light-emitting device is illustrated, but the light-emitting device is not limited to the surface mounting type device. The light-emitting device may be a cannonball type, a chip-on-board (COB) type, or a chip-scale-package (CSP) type.

The embodiments of the present invention have been described above, but these are examples of the present invention and various configurations other than the examples can also be adopted. In addition, the present invention is not limited to the above-described embodiment, and modifications, improvements, and the like within the range in which the object of the present invention can be achieved are included in the present invention.

### EXAMPLES

The embodiment of the present invention will be described in detail based on examples and comparative examples. It is noted, just to be sure, that the present invention is not limited to only Examples.

<Production Example of Nuclear Particles>

First, in a container, 60.60 g of α-type silicon nitride (Si₃N₄, manufactured by Ube Kosan Co., Ltd., SN-E10 grade), 53.12 g of aluminum nitride (AlN, manufactured by Tokuyama Corporation, E grade), and 7.30 g of europium oxide (Eu₂O₃, manufactured by Shin-Etsu Chemical Co., Ltd.) were added and premixed.

Next, in a glove box held in a nitrogen atmosphere in which moisture is adjusted to equal to or less than 1 ppm by mass and an oxygen concentration is adjusted to equal to or less than 50 ppm, in the container, 2.75 g of calcium nitride (Ca₃N₂, manufactured by Materion) and 116.23 g of strontium nitride (Sr₃N₂, purity of 2N, manufactured by High Purity Chemical Laboratory Co., Ltd.) were further added and dry-mixed. From the above, a raw material powder (mixed powder) was obtained.

In the glove box, a container with a lid made of tungsten was filled with 240 g of the above raw material powder. After closing the lid of this container with a lid, the container was taken out from the glove box and placed in an electric furnace including a carbon heater. After that, a pressure in the electric furnace was sufficiently vacuum-exhausted until the pressure became equal to or less than 0.1 PaG.

While continuing the vacuum exhaustion, a temperature inside the electric furnace was raised to 600° C. After the temperature reached 600° C., nitrogen gas was introduced into the electric furnace, and the pressure in the electric furnace was adjusted to 0.9 MPaG. After that, in the atmosphere of nitrogen gas, the temperature inside the electric furnace was raised to 1950° C., and after the temperature reached 1950° C., the heat treatment was performed for 8 hours. After that, the heating was finished and the mixture was cooled to room temperature. After the mixture was cooled to room temperature, red lumps were collected from the container. The collected lumps were crushed in a mortar and sieved to adjust the particle size so that a median diameter becomes 17 μm.

<Producing Phosphor Powder>

### Example 1

(1) In a container, 57.20 g of α-type silicon nitride (Si₃Na, manufactured by Ube Kosan Co., Ltd., SN-E10 grade), 50.14 g of aluminum nitride (AlN, manufactured by Tokuyama Corporation, E grade), 6.89 g of europium oxide (Eu₂O₃, manufactured by Shin-Etsu Chemical Co., Ltd.), and 12.00 g of nuclear particles produced above having a median diameter of 17 μm were added and premixed.

(2) Next, in a glove box held in a nitrogen atmosphere in which moisture is adjusted to equal to or less than 1 ppm by mass and an oxygen concentration is adjusted to equal to or less than 50 ppm, in the container, 1.09 g of calcium nitride (Ca₃N₂, manufactured by Materion) and 112.68 g of strontium nitride (Sr₃N₂, purity of 2N, manufactured by High Purity Chemical Laboratory Co., Ltd.) were further added and dry-mixed. Accordingly, a raw material powder (mixed powder) was obtained.

(3) In the glove box, a container with a lid made of tungsten was filled with 240 g of the above raw material powder. After closing the lid of this container with a lid, the container was taken out from the glove box and placed in an electric furnace including a carbon heater. After that, a pressure in the electric furnace was sufficiently vacuum-exhausted until the pressure became equal to or less than 0.1 PaG.

(4) While continuing the vacuum evacuation, a temperature inside the electric furnace was raised to 600° C. After reaching 600° C., nitrogen gas was introduced into the electric furnace, and the pressure in the electric furnace was adjusted to 0.9 MPa·G. After that, in the atmosphere of nitrogen gas, the temperature inside the electric furnace was raised to 1950° C., and after the temperature reached 1950° C., the heat treatment was performed for 15 hours. After that, the heating was finished and the mixture was cooled to room temperature. After the mixture was cooled to room temperature, red lumps were collected from the container.

(5) The collected lumps were crushed and passed through a sieve with an opening of 75 μm. After that, the collected lumps were crushed under conditions of 0.15 MPa×20 g/min using a JM pulverizer (manufactured by Nisshin Engineering Co., Ltd., model number: SJ-100C-CB). By doing so, a red phosphor (a fired powder) was obtained.

(6) A tungsten container was filled with the obtained fired powder, and the container was quickly transferred into an electric furnace including a carbon heater and sufficiently vacuum-exhausted until the pressure in the furnace became equal to or less than 0.1 PaG. Heating was started while the vacuum evacuation was continued, and when the temperature reached 600° C., argon gas was introduced into the furnace to adjust the pressure in the furnace atmosphere to atmospheric pressure. Even after the introduction of argon gas was started, the temperature was continuously raised to 1350° C. After the temperature reached 1350° C., the heat treatment was performed for 8 hours. After that, the heating was finished and the mixture was cooled to room temperature. After cooling to room temperature, the annealed powder was collected from the container. The collected powder was passed through a sieve to adjust the particle size. From the above, a red phosphor (annealed powder) was obtained.

(7) The annealed powder was added to 2.0 M of hydrochloric acid at room temperature so that the slurry concentration was 25, by mass, and immersed for 1 hour. Accordingly, the acid treatment was performed. After the acid treatment, a hydrochloric acid slurry was boiled for 1 hour while stirring. The slurry after the boiling treatment was cooled to room temperature and filtered, and an acid treatment liquid was separated from a synthetic powder. The synthetic powder after the acid treatment liquid separation was placed in a dryer having a temperature set in a range of 100° C. to 120° C. for 12 hours. An alumina crucible was filled with the dried powder after the acid treatment step, heated in the atmosphere at a heating rate of 10° C./min, and heated at 400° C. for 3 hours. After the heat treatment, it was left to stand until it reached room temperature.

From the above, the phosphor powder of Example 1 was obtained.

Powder X-ray diffraction using CuKα ray was performed on the obtained phosphor sample using an X-ray diffractometer (Ultima IV manufactured by Rigaku Corporation). In the obtained X-ray diffraction pattern, the same diffraction pattern as the CaAlSiN₃ crystal was recognized, and it was confirmed that a main crystal phase had the same crystal structure as that of the CaAlSiN₃ crystal.

### Comparative Example 1

A phosphor powder was obtained in the same manner as in Example 1, except that the following changes.

(i) The amount of each material mixed in a case of obtaining the raw material powder was set as Si₃N₄: 60.39 g, AlN: 52.94 g, Eu₂O₃: 8.41 g, Ca₃N₂: 2.43 g, Sr₃N₂: 115.83 g, and no nuclear particles were used.

(ii) The duration of the heat treatment at 1950° C. was set to 8 hours instead of 15 hours.

### Comparative Example 2

A phosphor powder was obtained in the same manner as in Example 1, except that the amount of each material mixed in a case of obtaining the raw material powder was set as Si₃N₄: 57.57 g, AlN: 50.46 g, Eu₂O₃: 6.93 g, Ca₃N₂: 2.62 g, Sr₃N₂: 110.42 g.

### Comparative Example 3

In a case where the powder obtained by the treatments up to (7) of Example 1 was classified by a sieve having an opening of 45 μm, a content remaining on the sieve was set as a phosphor powder of Comparative Example 3.

Hereinafter, the amount of nuclear particles used, the molar ratio of each element, correspondence of x, 1−x−y, and y in the general formula ((Srₓ, Ca_{1-x-y}, Eu_{y})AlSi(N,O)₃, and heating (sintering) conditions (the conditions of the step (4) of Example 1) of Example 1 and Comparative Examples 1 to 3 are collectively shown.

TABLE 1

| | | Element composition | | | | | | Heating (sintering) condition | | |
|---|---|---|---|---|---|---|---|---|---|---|
| | Nuclear | | | | Ca (molar | | Eu + | | | Atmosphere |
| | particles | Si (molar | Al (molar | Eu (molar | ratio) | Sr (molar | Sr + | Temperature | Time | pressure |
| | (% by mass) | ratio) | ratio) | ratio) [y] | [1 − x − y] | ratio) [x] | Ca | (° C.) | (hr) | (MPa · G) |
| Example 1 | 5 | 1 | 1 | 0.032 | 0.018 | 0.95 | 1.000 | 1950 | 15 | 0.8 |
| Comparative | 0 | 1 | 1 | 0.037 | 0.038 | 0.925 | 1.000 | 1950 | 8 | 0.8 |
| Example 1 | | | | | | | | | | |
| Comparative | 5 | 1 | 1 | 0.032 | 0.043 | 0.925 | 1.000 | 1950 | 15 | 0.8 |
| Example 2 | | | | | | | | | | |
| Comparative | 5 | 1 | 1 | 0.032 | 0.018 | 0.95 | 1.000 | 1950 | 15 | 0.8 |
| Example 3 | | | | | | | | | | |

<Measurement of Particle Size Distribution>

The measurement was performed by a laser diffraction scattering method in conformity with JIS R1629: 1997, using Microtrac MT3300EX II (manufactured by MicrotracBEL Corporation). 0.5 g of a phosphor powder was put into 100 cc of ion exchange water, the mixture was subjected to a dispersion treatment with Ultrasonic Homogenizer US-150E (Nissei Corporation, chip size: φ20 mm, Amplitude: 100%, oscillation frequency: 19.5 KHz, amplitude of vibration: about 31 μm) for 3 minutes, and then the particle size was measured with MT3300EX II. A value of D₅₀, a value of (D₉₀−D₁₀)/D₅₀, and the like were obtained from the obtained particle size distribution. The results are summarized in Table 2.

TABLE 2

| | D₁₀ | D₅₀ | D₉₀ | D₁₀₀ | D₉₇ | (D₉₀ − |
|---|---|---|---|---|---|---|
| | (μm) | (μm) | (μm) | (μm) | (μm) | D₁₀)/D₅₀ |
| Example 1 | 17.9 | 30.3 | 51.1 | 147.1 | 71.1 | 1.10 |
| Comparative | 10.6 | 17.9 | 31.3 | 87.5 | 44.7 | 1.16 |
| Example 1 | | | | | | |
| Comparative | 12.4 | 20.8 | 36.0 | 104.0 | 51.0 | 1.13 |
| Example 2 | | | | | | |
| Comparative | 31.3 | 48.8 | 79.0 | 247.3 | 114.8 | 0.98 |
| Example 3 | | | | | | |

<Manufacture of LED Package and Evaluation of Brightness>

The phosphor powder obtained in Example or Comparative Example was added to a silicone resin together with a YAG phosphor (manufactured by DAEJOO ELECTRONIC MATERIALS CO., LTD., product name: DLP-GY25A1, a peak wavelength: 530.4 nm, a median diameter: 21.5 μm), defoamed and kneaded to obtain a kneaded product.

A white LED was manufactured by potting this kneaded product in a surface mount type package to which a blue LED element having a peak wavelength of 450 nm was bonded and then thermosetting the kneaded product. Here, an addition amount ratio between the phosphor and the YAG phosphor was adjusted so that chromaticity coordinates (x, y) of the white LED became (0.380, 0.380) during energized light emission (specific addition amount ratio was shown in Table 3).

A total luminous flux during the energized light emission of the manufactured white LED was measured by a total luminous flux measurement device manufactured by Otsuka Electronics Co., Ltd. (a device obtained by combining an integrating hemisphere having a diameter of 500 mm and a spectrophotometer/MCPD-9800). This measurement was performed on 10 white LEDs in which chromaticity x was in a range of 0.370 to 0.390 and chromaticity y was in a range of 0.370 to 0.390, and an average value of the 10 obtained measured values was set to a final measured value. In addition, this evaluation result was a relative evaluation in a case where the average value of the total luminous flux of the white LED manufactured using the phosphor powder of Comparative Example 1 was set to 100.

TABLE 3

| | | | Evaluation result | |
|---|---|---|---|---|
| | Addition amount ratio | | | PKG brightness |
| | (% by mass) | | PKG | (vs Comparative |
| | YAG | SCASN | brightness | Example 1) |
| Example 1 | 94.5% | 5.5% | 100.3% | 100.8% |
| Comparative | 95.9% | 4.1% | 99.5% | 100.0% |
| Example 1 | | | | |
| Comparative | 95.3% | 4.7% | 99.3% | 99.8% |
| Example 2 | | | | |
| Comparative | 90.6% | 9.4% | 84.4% | 84.8% |
| Example 3 | | | | |

As shown in Table 3, by using a phosphor powder (a red phosphor) having a value of D₅₀ of more than 20 μm and 40 μm or less and a value of (D₉₀−D₁₀)/D₅₀ of 1.12 or less, a white LED having improved brightness could be obtained.

This application claims priority based on Japanese Patent Application No. 2021-047031 filed on Mar. 22, 2021, the disclosures of which are incorporated herein by reference in their entireties.

### REFERENCE SIGNS LIST

10 red phosphor
20 other phosphors
30 sealing material
40 composite
100 light-emitting device
120 light-emitting element
130 heat sink
140 case
150 first lead frame
160 second lead frame
170 bonding wire
172 bonding wire

1. A phosphor powder consisting of a red phosphor represented by a general formula (Srₓ, Ca_{1-x-y}, Eu_{y})AlSi(N,O)₃ having the same crystal phase as that of CaAlSiN₃,
wherein relationships of x<1 and 1−x−y>0 are satisfied, and
in a case where a cumulative 10% value of the phosphor powder in a volume-based particle size distribution curve is defined as D₁₀, a cumulative 50% value is defined as D₅₀, and a cumulative 90% value is defined as D₉₀, a value of D₅₀ is more than 20 μm and 40 μm or less, and a value of (D₉₀−D₁₀)/D₅₀ is 1.12 or less.

2. The phosphor powder according to claim 1,
wherein a peak wavelength of a fluorescence spectrum in a case where blue excitation light at a wavelength of 455 nm is emitted is 600 to 650 nm.

3. The phosphor powder according to claim 1,
wherein a relationship of y<0.1 is satisfied.

4. A composite comprising:
the phosphor powder according to claim 1; and
a sealing material that seals the phosphor powder.

5. A light-emitting device comprising:
a light-emitting element that emits excitation light; and
the composite according to claim 4, that converts a wavelength of the excitation light.
